(19) United States
(12) Patent Application Publication
(10) Pub. No.: US 2003/0102527 A1
(43) Pub. Date: Jun. 5, 2003

(54) Method of fabricating light emitting diode package

(76) Inventor: Bily Wang, Hsin-Chu (TW)

Correspondence Address: Hung Chang Lin, 8 Schindler Court, Silver Spring, MD, 20903, US

(21) Appl. No.: 10/232,863

(22) Filed: Sep. 30, 2002

Related U.S. Application Data
(62) Division of application No. 09/002,087, filed on Dec. 31, 1997, now abandoned.

(30) Foreign Application Priority Data
Dec. 18, 2001 (GB) 0130138.1

(51) Int. Cl. H01L 29/06

(52) U.S. Cl. 257/618

(57) ABSTRACT

A method of mass-producing light-emitting diodes (LED). An LED is mounted in a cup recessed in a common substrate. Light reflected from the calls of the cup is directed toward the viewer in front of the LED and is intensified. A lens can be imbedded in the cover of the package to further intensify the light. The common substrate is diced to yield a large number of LED packages.

### BACKGROUND

This is a Division of application of U.S. patent application Ser. No. 09/002,087, filed Dec. 31, 1997, now abandoned. This invention relates to light emitting diodes, in particular to packages for light emitting diodes.

In a conventional light emitting diode (LED) package, the LED is mounted on a printed circuit board. The design does not have any provision for focusing the light emitted from the LED. On the contrary, the light emitted from the LED is divergent, radiating in all directions. Thus, the light intensity in front of the LED is not strong.

FIG. 1 shows a conventional package. A light emitting diode 130 is attached to an insulating substrate 110. The LED has a first input terminal 131 and a second output terminal 132. The substrate has a printed circuit etched according to a particular design. The substrate has at least a first electrode 121 and a second electrode 122, which are wire-bonded to the terminals 131 and 132 respectively. Finally, the package is sealed by the dome-shaped sealing compound 199.

This kind of LED package has its emitted light radiating in all directions. Thus a viewer standing in front of the LED sees a weak light.

### SUMMARY

An object of this invention is to present an intensified light for the viewer standing in front of the LED. Another object of the present invention is to focus the light in a particular direction. Still another object of this invention is to provide a LED package, which is amenable to mass production for low cost.

The object is achieved by mounting the LED inside a cup-shaped recess in the substrate. The light reflected from the wall of the recess is directed toward the front of the LED, and is thus intensified. A lens can be incorporated on the cover of the package to further intensify the light.

### BRIEF DESCRIPTION OF THE INVENTION

FIG. 1 shows a prior art LED package.

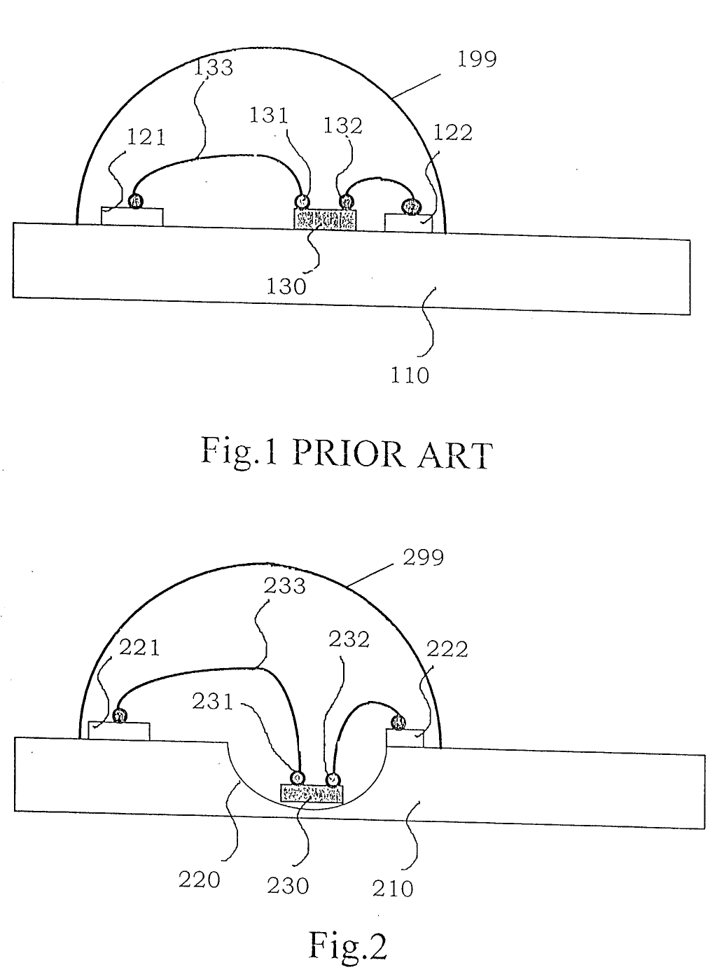

FIG. 2 shows a first embodiment of the focused light LED package of the present invention.

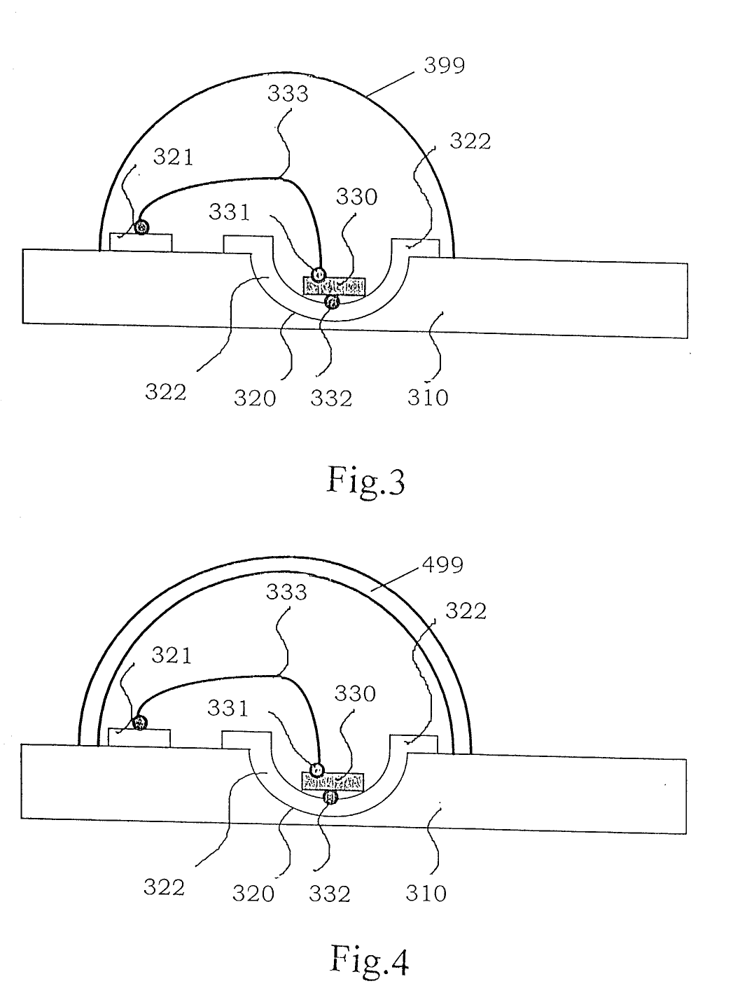

FIG. 3 shows a second embodiment of the focused light LED package. FIG. 4 shows an arc shaped cover for the LED package.

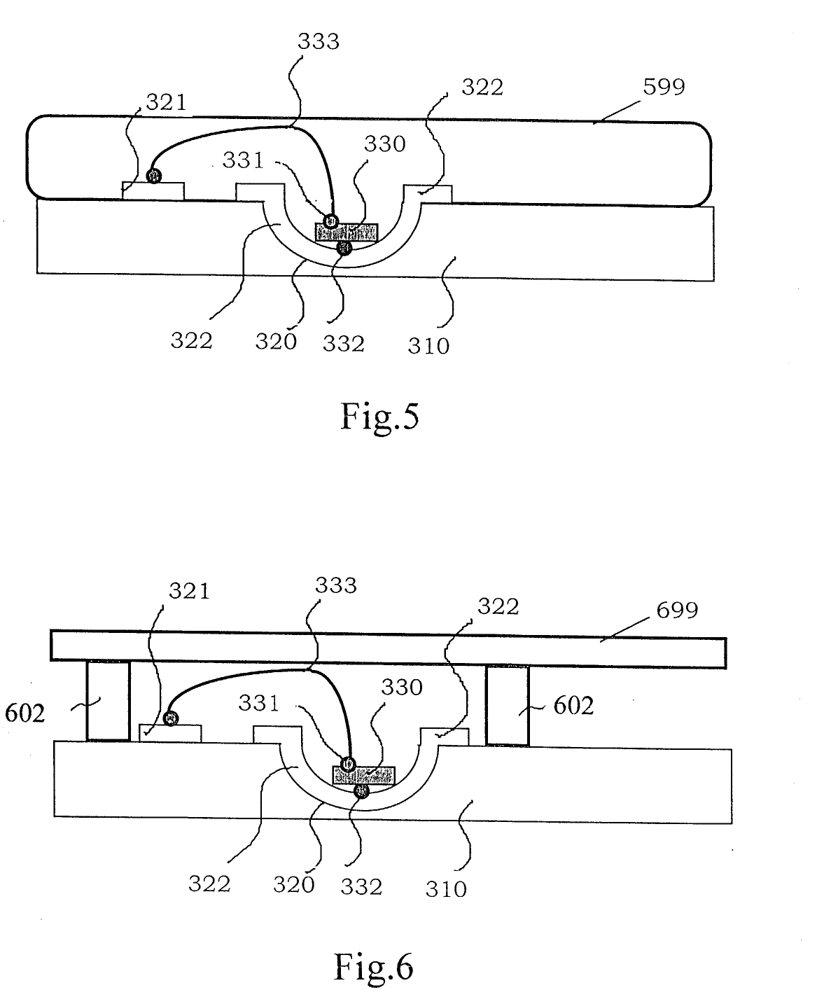

FIG. 5 shows a rectangular transparent seal for the LED package after dicing.

FIG. 6 shows a another LED package sealed with a transparent plate after dicing.

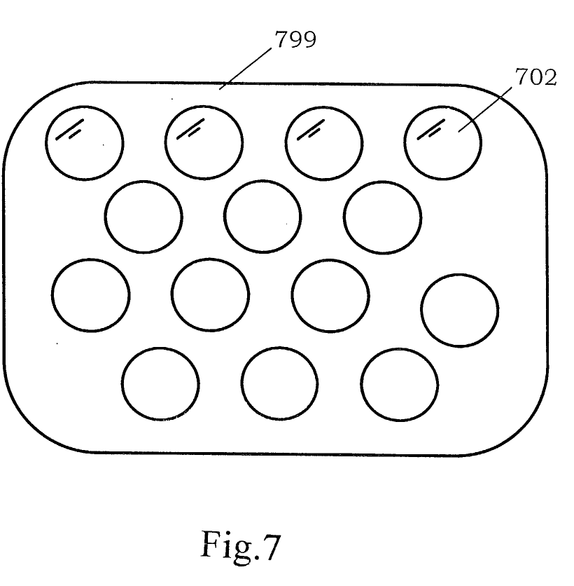

FIG. 7 shows focusing lenses imbedded in the transparent plate of FIG. 6 before dicing.

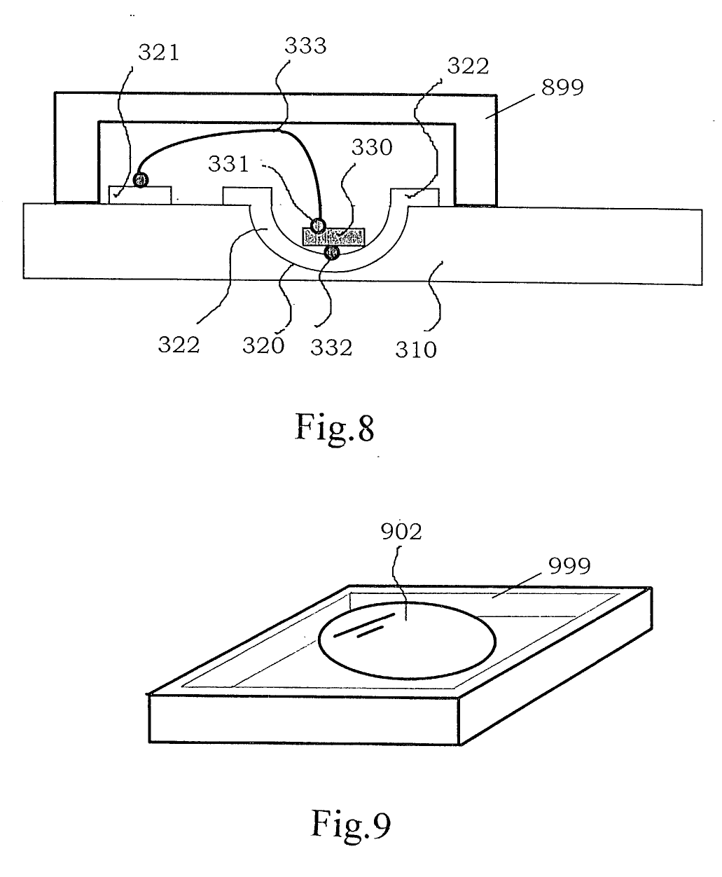

FIG. 8 shows a rectangular cover for a LED package of the present invention.

FIG. 9 shows a focusing lens imbedded in the cover shown in FIG. 8.

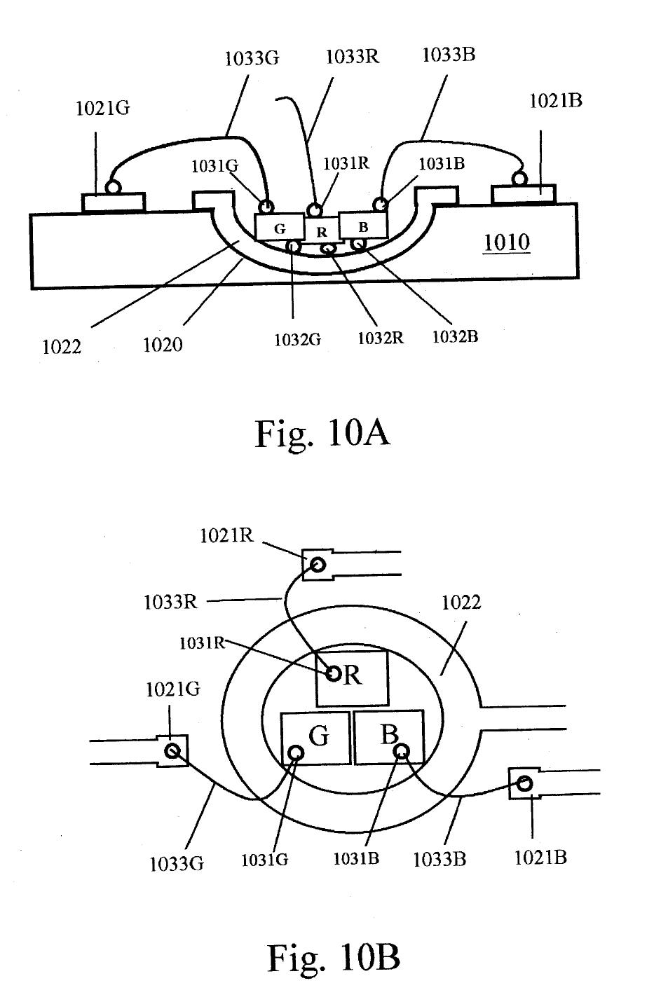

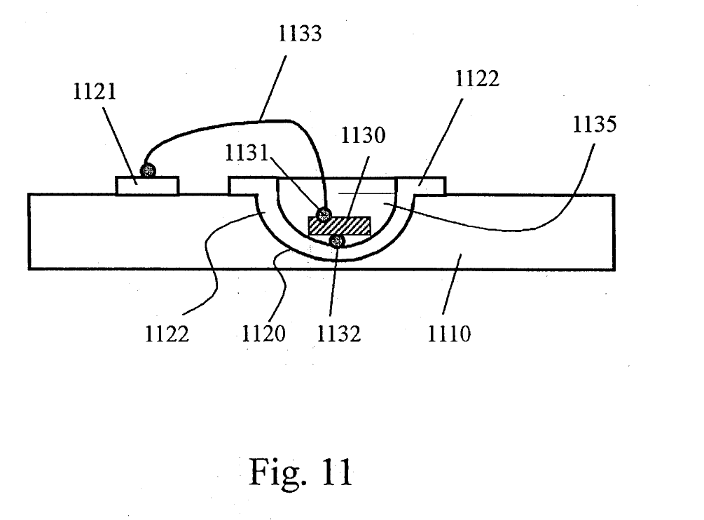

FIG. 10a shows the side view of a tri-color LED package; FIG. 10b shows the top view.

FIG. 11 shows the side view of a colorless LED package.

### DETAILED DESCRIPTION OF THE PREFERRED EMBODIMENT

FIG. 2 shows the recessed substrate of the present invention. A substrate 210 has a cup-shaped recess 220. A light emitting diode 230 is placed inside the recess 220. The cup-shaped seat can reflect light toward a direction of a viewer. Thus, with the same LED, a stronger light intensity can reach the viewer than the conventional package shown in FIG. 1.

The light emitting diode 230 is fixed inside the recessed cup 220. The LED 230 has a first input terminal 231 and an output terminal 232. The printed circuit substrate 210 has pre-etched circuit patterns, which at least include a first electrode 221 and a second electrode 222 wire-bonded to the LED terminals 231 and 232 respectively. Finally, the package is sealed within the confines of seal 299, inside which the LED 230, the first terminal 231, the second terminal 232 and the bonding wire 233 are covered.

FIG. 3 shows a modified structure of FIG. 2. The LED 330 is fixed inside a recessed cup 320. The surface of the cup is coated with a conducting metal 322. Because the metal has good light reflecting property, the reflected focused light can be further intensified. The LED 330 has a first output terminal 331 and an input terminal 332. The substrate has a pre-designed printed circuit, which contains at least a first electrode 321 which is wire-bonded to the first terminal 331 of the LED 330 through the wire 333. The second electrode 322 on the substrate is formed as a flange of the recessed cup 320 and is connected to the input terminal 332 of the LED 330. Finally, the LED 330, the first electrode 331, the second electrode 332 and the bonding wire 333 are all imbedded inside the seal 399.

In FIG. 4, the assembly of the recessed LED, bonding wire and the electrodes shown in FIG. 3 are covered with a cap 499 instead of a seal 399. The cap is sealed at the edge between the cap 499 and the substrate 310. Other parts such as 320, 331, 332 and 333 serve the same functions as corresponding parts with the same reference numerals in FIG. 3. By placing a cap over the LED 330 and the electrodes 321 and 322 on a common substrate, thousands of LED packages can be capped and sealed at the same time.

FIG. 5 shows another sealing method for the LED package. The sealing compound covers a large number of LED assemblies similar to those shown in FIG. 3 on a common substrate. The reference numerals for the parts in FIG. 5 are the same as corresponding parts in FIG. 3. After dicing, an individual LED package has a rectangular seal 599 as shown in FIG. 5.

FIG. 6 shows another sealing method. A transparent glass plate 699 is placed on top of the LED assembly and supported glued pillars 602. The reference numerals for the parts in FIG. 6 are the same as corresponding parts in FIG. 3. Again, a large number of LED packages can be fabricated on a common substrate, which is later diced to yield individual packages.

FIG. 7 shows another modification of FIG. 6 for focusing the light emitted from the LED. A number of lenses 702 are imbedded in the glass plate 799 (corresponding to glass plate 699 in FIG. 6.). These lenses further focus the light toward the viewer for greater intensity.

FIG. 8 shows a rectangular cap 899 covering the LED assembly in stead of the dome-shaped cover used in FIG. 4. The reference numerals for the parts in FIG. 8 are the same as corresponding parts in FIG. 3.

FIG. 9 shows a focusing lens 902 imbedded in the rectangular cover 999 (corresponding to the rectangular cover 899 in FIG. 8) for the structure shown in FIG. 8.

FIG. 10a shows the side view of a tri-color LED package. The substrate 1010 has a cup-shaped recess 1020. The cup is coated with a reflecting metal layer 1022 for intensifying the reflecting beam. There are three light emitting diodes mounted inside the cup: a red LED R with input and output terminals 1031R and 1032R; a blue LED B with input and output terminals 1031B and 1032B; and a green LED with input and output terminals 1031G and 1032G. The terminals 1031R, 1031B and 1031G are individually wire bonded by wires 1033R, 1033B, 1033G to bonding pads 1021R, 1021B and 1021G respectively, also shown in the top view of the package in FIG. 10B. The brightness of the R, B and G LEDs can be individually controlled to yield a desired color.

FIG. 11 shows the side view of a colorless LED package. The substrate 1010 has cup-shaped recess 1020 which is coated with a reflecting metal layer 1022 for increasing reflecting. A LED 1030 is mounted in the cup with input and output terminals 1031 and 1032. The upper terminal 1031 is wire bonded to a bonding pad 1021 through a wire 1033. The lower terminal 1032 is attached to the metal surface 1022. The cup is filled with a transparent material 1035b up to just below the top surface of the substrate. Another thin layer of phosphorescence material 1035a is coated above the transparent layer 1035b. The phosphorescence material 1035a emits a colorless light, when the LED 1030 is excited. By using a layer of phosphorescence material 1035a instead of filling the entire cup with phosphorescence material, one can save the phosphorescence material.

While the preferred embodiments of the invention have been shown and described, it will be apparent to those skilled in this art that various modifications may be made in the embodiments without departing from the spirit of the present invention. Such modifications are all within the scope of this invention.

What is claimed is:

1. A method of mass producing light emitting diode (LED) package, each fabricated on a common substrate and having a recessed cup in said common substrate, a LED mounted in said recessed cup which reflects light emitted from said LED in a direction perpendicular to the planar surface of said substrate, a first electrode and a second electrode on said common substrate connected to a first terminal and a second terminal of said LED respectively, comprising the steps of:
forming a matrix of recessed cups in a common substrate;
mounting a LED in each one of said recessed cups;
connecting electrodes of each one of said LED to corresponding terminals on said substrate; covering said common substrate with a sealing compound, and
dicing through said sealing compound to yield a large number of individual said LED packages.

2. The method of mass producing LED packages as described in claim 1, wherein said recessed cups are formed by electroplating.

3. The method of mass producing LED packages as described in claim 1, wherein said recessed cups are coated with a metallic layer to enhance reflection.

4. A method of mass producing LED packages, each fabricated on a common substrate and having a recessed cup in said common substrate, a LED mounted in said recessed cup which reflects light emitted from said LED in a direction perpendicular to the planar surface of said substrate, a first electrode and a second on said common substrate connected to a first terminal and second terminal of said LED respectively, comprising the steps of:
forming a matrix of recessed cups in a common substrate;
mounting a LED in each one of said recessed cups;
connecting electrodes of each one of said corresponding terminals on said substrate;
covering above said common substrate with a transparent cap; and
dicing through said transparent plate to yield a large number of individual said LED packages.

5. The method of mass producing LED packages as described in claim 4, wherein said recessed cups are formed by electroplating.

6. The method of mass producing LED packages as described in claim 4, wherein said cover is imbedded with a focusing lens.
